(19) United States
(12) Patent Application Publication
(10) Pub. No.: US 2004/0077112 A1
(43) Pub. Date: Apr. 22, 2004

(54) Conductive component manufacturing process employing an ink jet printer

(76) Inventor: Stephen J. Elliott, Sacramento, CA (US)

Correspondence Address: HEWLETT-PACKARD COMPANY, Intellectual Property Administration, P.O. Box 272400, Fort Collins, CO, 80527-2400, US

(21) Appl. No.: 10/273,782

(22) Filed: Oct. 18, 2002

(51) Int. Cl. H01L 21/00

(52) U.S. Cl. 438/21

(57) ABSTRACT

The present invention relates to conductive components manufacturing processes employing conventional direct transfer printers to make components such as printer circuit boards and semiconductors, by way of non-limiting example. The process disclosed allow for the production of customized conductive components, particularly prototype components, utilizing in a convenient, cost effective manner.

### FIELD OF THE INVENTION

The present invention relates to a conductive component manufacturing processes and, more particularly, to processes for manufacturing conductive components such as circuit boards and semiconductors employing a direct transfer printer such as an ink jet printer.

### BACKGROUND OF THE INVENTION

Conductive components such as circuit boards are generally processed in sterile environments by complex robotic apparatuses. For example, circuit boards are currently manufactured by applying a vast array of small components such as resistors via soldering to an etched metal board. The attachment of such components generally occur at high temperatures which can damage the components or alter the desirable characteristics of the substrate to which they are applied. As can be appreciated, the foregoing circuit board manufacturing process is expensive and complex in that specialized robotic apparatuses must be designed and used for both prototyping and product manufacture. Still another perceived disadvantage relates to the undue thickness of the resulting circuit board which imparts connection density.

### SUMMARY OF THE INVENTION

In an effort to address one or more of the above mentioned disadvantages, among others, the conductive component manufacturing process of the present invention generally comprises the steps of:

a) providing a direct transfer printer having a print head connected to a transfer medium cartridge including multiple compartments wherein at least one compartment includes a composition selected from conductive compositions, masking agents, etchants, dopants and solvents;

b) bringing said substrate sheet in proximity to said print head; and

c) applying at least one composition through said print head onto said substrate sheet in a selected area to form a conductive component.

While the commercial production of conductive components is envisioned, the processes of the present invention are particularly suited for rapid prototyping of circuit boards and semiconductors, by way of non-limiting example. Further, the processes of the present invention offer a self contained system for manufacturing conductive components. Still another object of the present invention is to manufacture conductive components employing commercially available desk top ink jet printers.

Among the numerous problems in the art which are addressed by the processes of the present invention is a reduction in the expense associated with currently employed prototyping processes. Further, resistors and capacitors are more fully integrated as opposed to soldered components which easily become displaced. Yet another advantage of the present processes are that they can be carried out at room temperatures, often in non-clean room environments. Additionally, the substrates employed such as metal or polymer coated sheets are much thinner than circuit boards thereby enhancing connection densities.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a perspective view of a conductive component manufacturing system assembly including a computer and an ink jet printer for carrying out the manufacturing processes of the present invention;

FIG. 2 is a side view showing a transfer medium cartridge and substrate sheet for the production of a circuit board;

FIGS. 3a-3c is a progressive assembly view of the circuit board manufacturing process;

FIG. 4 is a side view showing a transfer mechanism cartridge and substrate sheet for the production of an optical semiconductor;

FIGS. 5a-5d is a progressive assembly view of an optical semiconductor manufacturing process;

FIG. 6 is a side view showing a transfer medium cartridge and substrate sheet for the production of an electrical semiconductor; and

FIGS. 7a-7d are a progressive assembly view of an electrical semiconductor manufacturing process.

### DETAILED DESCRIPTION OF THE PREFERRED EMBODIMENTS

The following description of the preferred embodiment(s) is merely exemplary in nature and is in no way intended to limit the invention, its application, or uses.

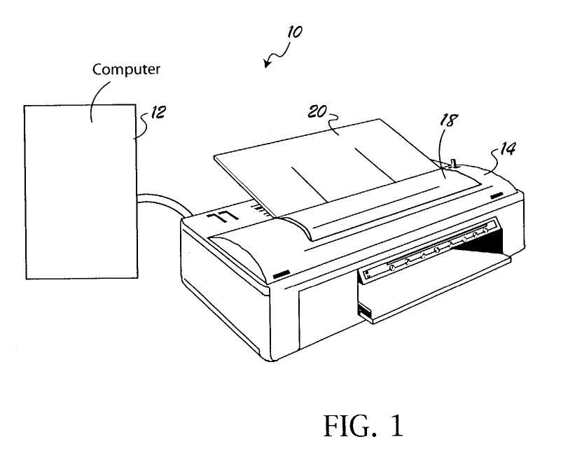

Referring to FIG. 1, there is shown a manufacturing system assembly 10 including a computer 12 and a conventional desk top direct transfer printer such as an ink jet printer 14. The computer may be selected from many commercially available models or may be custom built provided that the computer includes a microchip or is software compatible to provide the printer with the appropriate signals to carry out the desired printing function.

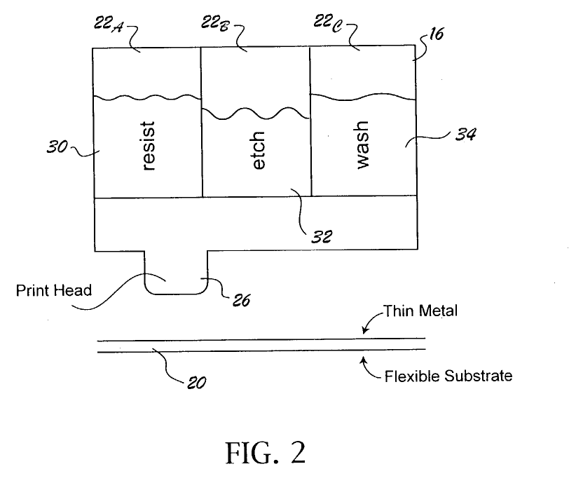

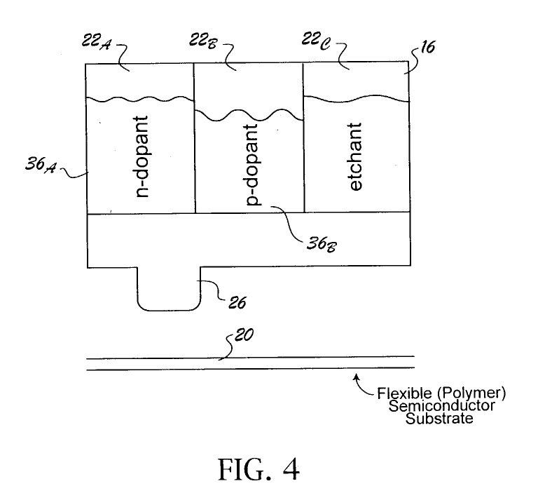

The printer 14 is generally a commercially available ink jet printer model including as key components a print cartridge 16 as shown in FIG. 2, otherwise referred to herein as a transfer medium cartridge and at least one tray 18 for hosting the printable substrate sheets 20. Although an embodiment employing what is commonly referred to as an ink cartridge is not shown, it should be understood that the phrase transfer medium cartridge encompasses both ink cartridges and print cartridges. As shown in FIGS. 2, 4 and 6, the transfer medium cartridge preferably includes multiple compartments designated as 22A-D, depending on the embodiment for hosting different treatment mediums such as conductive compositions, masking compositions (resist), etching compositions, dopants and solvents (cleaning solutions). Connected to the transfer medium cartridge is a print head 26 capable of transferring compositions from the transfer medium cartridge to the substrate sheet.

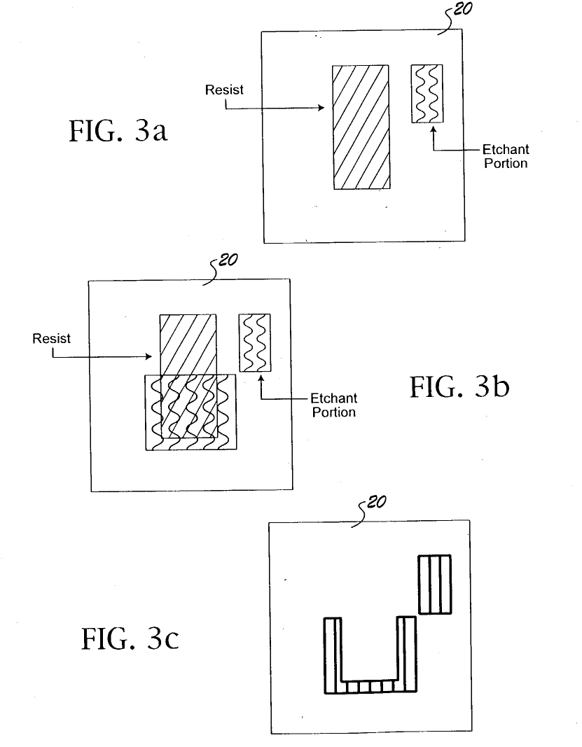

Referring to FIGS. 3a-3c, a method of manufacturing a circuit board assembly utilizing conventional ink jet printing components as set forth above will now be described. Initially the transfer medium cartridge is filled with the necessary compositions such as a masking (resist) composition 30, an etchant composition 32 and a cleaning solution 34 and is installed in the printer. A substrate sheet 20 is also installed on the printer. Once the printer is set up, the computer signals the printer to carry out a predetermined print function.

For example, as illustrated in FIG. 3a, the computer initially may instruct the printer to cause a masking composition to be applied by the print head to a selected area of the substrate sheet. Among the proposed masking compositions are non-conductive inks and plastic solutions, by way of non-limiting example.

An etchant composition may then be applied in a specific pattern to selected areas of the substrate sheet as illustrated in FIG. 3b including areas overlapping any masking patterns which have been applied. The etching compositions can be in the form of acids such as hydrochloric acid (for etching glass and metal), water (for etching salts) or solvents (for etching metal or plastic). A particularly useful etchant for copper would be iron tetrachloride. Photoluminescent dyes could also be used to locally expose a photoresist to act as an etchant. The principle property is that the etchant prepares the surface for further removal of material and distinguishes the surface from non-etching regions.

Thereafter, a cleaning solution (wash) may be applied to the substrate through the print head to remove the masking composition. The cleaning solution can consist of standard plastic solvents, water, acetone or any component which consumes the “waste”, possibly converting it to a gas. By following the foregoing steps, a circuit board as shown in FIG. 3c can be generated having the desired array of resistors.

It should be understood that the substrate sheet may be supplied in a prefabricated condition to include maskings or etchants, for example, thus eliminating or reducing the application steps to be carried out by the printer. Among the numerous types of substrate sheets that can be used are paper, plastic, plastic coated paper, thin metal sheets, metal coated paper, quartz and cloth, by way of non-limiting example. Paper should be of a uniform surface quality or supplemented with a plastic or other coating to create a surface of sufficient uniformity to consistently deposit the various layers. Thin metal such as copper leaf on the paper or other metal leaf on paper can be used to pattern electronic circuits where soldering is also required. The metals primarily used for the thin metal sheets, otherwise referred to as metal leaf, are aluminum, copper, tin, lead, and silver. Quartz can be used in optical applications or as a substrate where lattice matching is required. Silicon can be applied in small thin squares on top of a polymer substrate so that regular patterning might be applied. Copper leaf on paper or cloth or other flexible material of dielectric consistency can be used for electronic circuits. Smaller substrates can be pre-mounted or mounted on larger substrates to make the manufacturing process more flexible.

In addition to the manufacture of printed circuit boards, the conductive component manufacturing system of the present invention may also be utilized to manufacture optical semi-conductors.

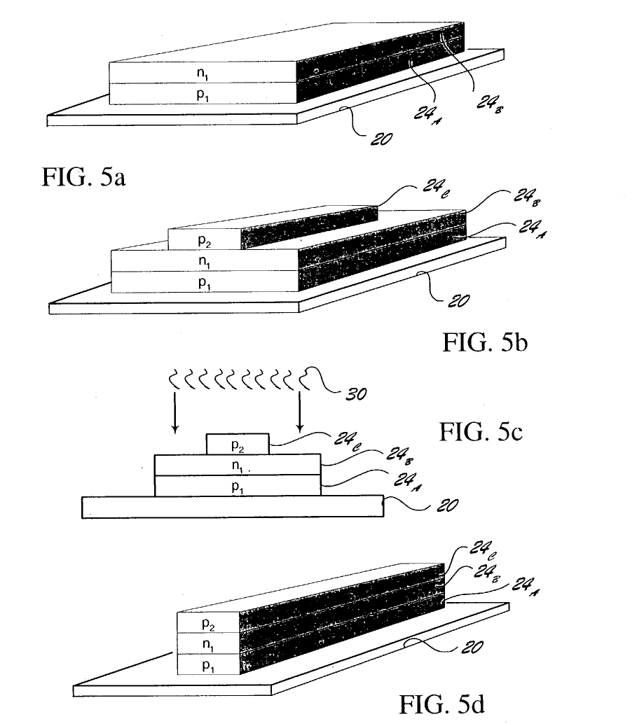

Again, a computer as shown in FIG. 1 is utilized to provide the printer with the appropriate signals necessary to carry out the desired print function. As shown in FIG. 5a, for example, a substrate sheet 20 is provided with a pre-printed dopant layer formed from a first dopant composition 36A and the optically enabled composition 36B.

With the substrate 20 and pre-printed layers in place, the printer is instructed to introduce a dopant composition 36C to form a second dopant layer applied over the optically enabled layer. It should be understood that the second dopant composition 36C may be the same as the first dopant composition 36A or different, provided it has a similar conductivity to the third dopant composition 36C. For example, when forming a p-n-p type semiconductor, the first and third dopants 36A, 36C, respectively, could be a cobalt inclusive material and the second composition 36B may be an acrylate. It should be noted that the dopants or other conductive compositions need not be organic derivative and further do not require pre-mixing in evaporable solvents to be successfully applied.

After the second dopant layer is formed, it may be necessary to apply an etchant to strip away any excess along with any “waste” portion of the dopant layers, possibly converting it to a gas. Thus, the printer is further instructed by the computer to apply one or more etchant compositions as illustrated in FIG. 5c. As a result of the application of the etchant, an optical semiconductor as shown in FIG. 5d can be achieved.

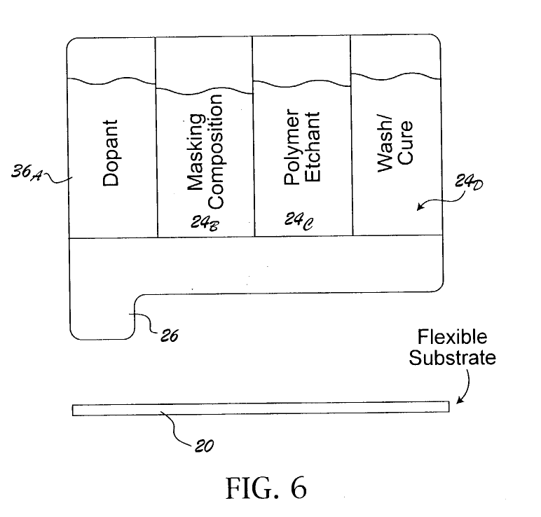

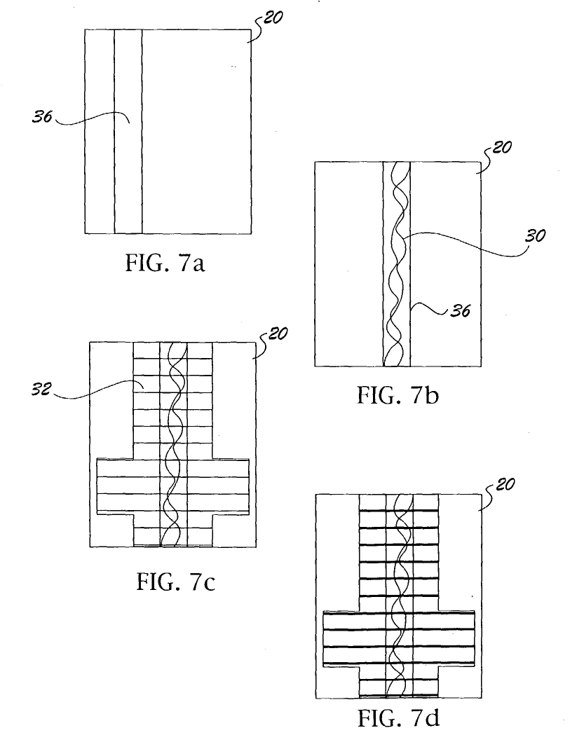

An electrical semiconductor is demonstrated as being manufactured utilizing an ink jet printer with reference to FIGS. 6 and 7a-7d. In this case, the print cartridge 16 is generally supplied with at least one dopant 36, masking composition 30, an etchant 32 and, optionally, a curing agent or washing solution 34 all shown in FIG. 6. Initially, the computer signals the printer to apply the dopant through the print head to the substrate 20 as demonstrated by FIG. 7a. Thereafter, a masking agent is deposited over the dopant as illustrated in FIG. 7b. Dopant compositions for electrical semiconductor applications would be selected from phosphorous, arsenic, silicon and germanium by way of non-limiting. Other, dopant materials commonly known in the production of semiconductors are also contemplated.

Next, an etchant 32 is deposited by the print head to the substrate, overlapping at least a portion of the dopant and masking agent as depicted in FIG. 7c. If necessary, a curing agent and/or washing solution 34 can then be applied over the etchant as shown in FIG. 7d to give a useful electrical semiconductor.

The present invention does not require the materials contained in the compartments of the transfer medium cartridge to include an evaporable component mixed with the component intended for application to the substrate. The present invention can apply inorganic as well as organic printing chemicals in the same print cycle. For example, by applying a combination of organic and inorganic materials in the same print cycle cost effectiveness can be improved and greater flexibility is afforded in combining materials to be printed for producing a printed circuit.

The present invention provides a complete system for producing a printed circuit board or semi conductor component as described above. In particular, all functions of producing a printed circuit, e.g., masking, etching and cleaning, can be performed using the same inkjet printer provided that the various components of the transfer medium cartridge are supplied with appropriate solutions. The present invention can also be configured to allow for further post-processing of printed circuits by processes or devices external to the invention.

The description of the invention is merely exemplary in nature and, thus, minor process variations are intended to be within the scope of the invention. Such variations are not to be regarded as a departure from the spirit and scope of the invention.

What is claimed is:

1. A conductive component manufacturing process comprising the steps of:
a) providing a direct transfer printer having a print head connected to a transfer medium cartridge including multiple compartments wherein at least one compartment includes a composition selected from conductive compositions, masking agents, etchants, dopants, and solvents;
b) bringing said substrate sheet in proximity to said print head; and
c) applying at least one composition through said print head onto said substrate sheet in a predetermined pattern to form a conductive component.

2. The conductive component manufacturing process of claim 1 wherein said substrate sheet is formed from a material selected from the group consisting of paper, plastic, plastic coated paper, thin metal sheets, metal coated paper, quartz and cloth.

3. The conductive component manufacturing process of claim 1 wherein said etchants are selected from the group consisting of acids, water, solvents and photoluminescent dyes.

4. The conductive component manufacturing process of claim 1 wherein said dopants are selected from the group consisting of phosphorous, arsenic, silicon and germanium.

5. The conductive component manufacturing process of claim 1 wherein said direct transfer printer is an ink jet printer.

6. The conductive component manufacturing process of claim 1 wherein the resultant conductive component is an electrical semiconductor.

7. The conductive component manufacturing process of claim 6 wherein said semiconductor is an optical semiconductor.

8. The conductive component manufacturing process of claim 1 wherein the printed circuit board.

9. The conductive component manufacturing process of claim 1 further comprising a computer linked to said printer to control the print function of said printer.

10. A process for producing conductive components comprising the steps of:
a) providing a direct transfer printer having a print head connected to a transfer medium cartridge including multiple compartments wherein each compartment includes a different composition selected from conductive compositions, masking agents, etchants, dopants, and solvents;
b) bringing said substrate sheet in proximity to said print head; and
c) sequentially applying at least two different compositions through said print head onto said substrate sheet in a predetermined pattern to form a conductive component.

11. The process of claim 10 wherein said substrate sheet includes a pre-printed first dopant composition to which said at least one composition is applied through a print head.

12. The process of claim 11 wherein said at least one composition includes an optically enabled composition applied through said print head over said first dopant composition and a second dopant composition applied through said print head over said optically enabled composition to form an optical semiconductor.

13. The process of claim 12 wherein said optically enabled composition is an acrylate.

14. The process of claim 12 wherein said first dopant composition and said second dopant composition are cobalt inclusive materials.

15. The process of claim 10 wherein an electrical semiconductor prototype is manufactured by
i) applying a dopant to said substrate through said print head;
ii) applying a masking agent over at least a portion of the dopant through said print head;
iii) applying an etchant over at least a portion of said dopant and masking agent through said print head; and
iv) optionally applying a masking agent through said print head to remove the etchant.

16. The process of claim 10 wherein a circuit board prototype is manufactured by
i) applying a masking composition through the print head over a predetermined position of the substrate;
ii) applying an etchant composition through the print head over a predetermined portion of the substrate; and
iii) applying a cleaning solution through the print head to remove the etchant.

17. A conductive component manufacturing process comprising the steps of:
a) providing a self contained printing system including a direct transfer printer having a print head connected to a transfer medium cartridge including multiple compartments wherein at least one compartment includes a conductive composition and at least one other compartment includes a composition selected from the group consisting of masking agents, etchants, dopants and solvents;
b) bringing said substrate sheet in proximity to said print head; and
c) applying at least one conductive composition and at least one composition selected from the group consisting of masking agents, etchants, dopants and solvents through said print head onto said substrate sheet in predetermined areas to form a conductive component.
